(19) United States
(12) Patent Application Publication
(10) Pub. No.: US 2026/0135578 A1
(43) Pub. Date: May 14, 2026

(54) WIRELESS COMMUNICATIONS SYSTEM CONFIGURED TO SUPPRESS TRANSMITTER NOISE AND HARMONIC DISTORTION IN WIRELESS TRANSMISSION SIGNALS AND METHOD FOR PERFORMING THE SAME

(71) Applicant: ELBIT SYSTEMS C4I AND CYBER LTD., Netanya (IL)

(72) Inventors: Avraham HAGAY, Netanya (IL); Mark WAISBLAY, Netanya (IL); Nimrod GINZBERG, Netanya (IL)

(21) Appl. No.: 19/443,093

(22) Filed: Jan. 8, 2026

Related U.S. Application Data
(63) Continuation of application No. PCT/IL2024/050696, filed on Jul. 16, 2024.

(30) Foreign Application Priority Data
Aug. 23, 2023 (IL) 305460

(51) Int. Cl. H04B 1/04

(52) U.S. Cl. CPC H04B 1/0475; H04B 2001/0491

(57) ABSTRACT

A wireless communications system comprises a transmitter and a narrowband filters bank coupled between the transmitter and a transmission antenna. The filters bank includes tunable narrowband filters that are capable of operating at a Radio Frequency (RF) power of 50 Watts or more. The system further comprises a power detector, a phase detector and a controller. The power detector detects a forward and reflected power of a given wireless signal at the transmission antenna. The phase detector detects a phase of the given wireless signal at the transmission antenna. The controller determines a phase change in a modulated digital RF signal associated with the given wireless signal, based on the detected phase, and, based on the detected forward and reflected power and the phase change, tunes a given tunable narrowband filter, of the tunable narrowband filters, that filters the given wireless signal.

### TECHNICAL FIELD

The invention relates to a wireless communications system that is configured to suppress transmitter noise and harmonic distortion in wireless transmission signals and a method for performing the same.

### BACKGROUND

High-power transmitters in wireless communications (e.g., radio) systems generate wireless transmission signals that include transmitter noise and harmonic distortion. Conventionally, harmonic filters are provided between the transmitter of a wireless communications system and a transmission antenna in order to reduce the harmonic distortion in wireless transmission signals that are transmitted by the wireless communications system over a wireless communications network. However, even with the use of such harmonic filters, transmitter noise and/or harmonic distortion in the transmitted wireless transmission signals (out of transitions band) can be of a signal strength greater than a receiver sensitivity of receivers within the wireless communications network. Accordingly, a receiver within the wireless communications network may fail to detect sensitivity signals due to transmitter noise and/or harmonic distortion. For example, in a Full Duplex (FD) wireless communications system, particularly a FD wireless communications system in which the transmitter and the receiver share a common frequency band, the receiver of the FD wireless communications system may fail to detect sensitivity signals that are received by the receiver concurrently to the transmission of a wireless transmission signal, by the transmitter of the FD wireless communications system, due to transmitter noise and/or harmonic distortion in the transmitted wireless transmission signal.

Accordingly, there is a need for a new wireless communications system and method for better suppressing transmitter noise and/or harmonic distortion in wireless transmission signals.

References considered to be relevant as background to the presently disclosed subject matter are listed below. Acknowledgement of the references herein is not to be inferred as meaning that these are in any way relevant to the patentability of the presently disclosed subject matter.

U.S. Patent Application Publication No. 2017/0033761, published on Feb. 2, 2017, discloses methods and apparatus, including computer program products, that are provided for a tunable filter. In some example embodiments, there may be provided an apparatus. In some example embodiments, there is provided an apparatus. The apparatus may include a tunable radio frequency filter including a tunable phase shifter coupled to a resonator, wherein the tunable phase shifter tunes a center frequency of the tunable radio frequency filter by at least varying a phase of a radio frequency signal provided to the resonator. Related apparatus, systems, methods, and articles are also described.

U.S. Pat. No. 9,960,748, published on May 1, 2018, discloses methods and apparatus, including computer program products, that are provided filters. In some example embodiments, there is provided a radio frequency filter including at least one resonant circuit selectable to vary at least the selectivity of the radio frequency filter, wherein the selectivity is varied based on at least one of a first amount of transmit power being used at a user equipment and a second amount of received signal power. Related apparatus, systems, methods, and articles are also described.

U.S. Patent Application Publication No. 2010/0321086, Published on December 23, 2010, discloses exemplary embodiments that are directed to power and impedance measurement circuits that may be used to measure power and/or impedance. A measurement circuit may include a sensor and a computation unit. The sensor may sense (i) a first voltage signal across a series circuit coupled to a load to obtain a first sensed signal and (ii) a second voltage signal at a designated end of the series circuit to obtain a second sensed signal. The sensor may mix (i) a first version of the first sensed signal with a first version of the second sensed signal to obtain a first sensor output and (ii) a second version of the first sensed signal with a second version of the second sensed signal to obtain a second sensor output. The computation unit may determine the impedance and/or delivered power at the designated end of the series circuit based on the sensor outputs.

U.S. Patent Application Publication No. 2010/0308933, published on Dec. 9, 2010, describes tunable matching circuits for power amplifiers. In an exemplary design, an apparatus may include a power amplifier and a tunable matching circuit. The power amplifier may amplify an input RF signal and provide an amplified RF signal. The tunable matching circuit may provide output impedance matching for the power amplifier, may receive the amplified RF signal and provide an output RF signal, and may be tunable based on at least one parameter effecting the operation of the power amplifier. The parameter(s) may include an envelope signal for the amplified RF signal, an average output power level of the output RF signal, a power supply voltage for the power amplifier, IC process variations, etc. The tunable matching circuit may include a series variable capacitor and/or a shunt variable capacitor. Each variable capacitor may be tunable based on a control generated based on the parameter(s).

U.S. Patent Application Publication No. 2010/0302106, published on Dec. 2, 2010, relates to impedance tuning of transmitting and receiving antennas.

U.S. Pat. No. 5,291,516, published on Mar. 1, 1994, discloses a dual-mode transmitter having an antenna, a mode controller, a source encoder, a tunable-frequency synthesizer, a chip-code generator, a spread-spectrum modulator, a narrowband modulator, a power amplifier, and an adjustable bandpass filter. Also provided is a dual-mode receiver having a mode controller, a tunable-frequency synthesizer, a chip-code generator, an antenna, an adjustable bandpass filter, a preamplifier, a frequency converter, an IF amplifier, a spread-spectrum de-spreader, a spread-spectrum demodulator, a narrowband modulator, and a source decoder. For the transmitter and receiver, the mode controller selects receiving a narrowband modulation or a spread-spectrum modulation. The tunable-frequency synthesizer generates a local oscillator signal for the receiver, and a carrier signal for the transmitter. The chip-code generator generates a chip code signal for both the transmitter and the receiver. With a narrowband modulation setting of the mode controller, the transmitter and receiver have the adjustable bandpass filters adjusted to a narrowband width for telephone communications. With a spread-spectrum setting of the mode controller, the adjustable bandpass filters and the system are adjusted to transmit and receive a wide bandwidth for passing the spread-spectrum signal.

U.S. Pat. No. 7,567,782, published on Jul. 28, 2009, provides methods and apparatus to enable a transceiver or transmitter including a single PA line-up to transmit signals having frequencies in two or more different frequency bands, and/or having two or more different modulation types, and/or having two or more different RF power levels. The single PA line-up includes at least one variable matching circuit and a variable harmonic filter to tune match and tune filter communication signals prior to transmission. The variable matching circuit and the variable harmonic filter each include at least one variable capacitive element that switches ON/OFF depending on whether a low frequency signal or a high frequency signal is being transmitted. Each variable capacitive element includes separate direct current and radio frequency terminals to enable the single PA line-up to change signal modulation and/or RF power levels in addition to frequencies.

U.S. Patent Application Publication No. 2016/0020862, published on Jan. 21, 2016, discloses an apparatus comprising a transmit path that includes a power amplifier load tuner having an adjustable impedance. The apparatus also includes a receive path that includes a receive tuner having an adjustable impedance. The apparatus further includes an antenna tuner having an adjustable impedance. The antenna tuner is coupled to the transmit path and to the receive path.

### GENERAL DESCRIPTION

In accordance with a first aspect of the presently disclosed subject matter, there is provided a wireless communications system, comprising: a transmitter configured to generate one or more wireless transmission signals; a narrowband filters bank including a plurality of tunable narrowband filters that are capable of operating at a Radio Frequency (RF) power of 50 Watts or more, the narrowband filters bank being coupled between the transmitter and a transmission antenna, wherein, for each of the wireless transmission signals, a respective tunable narrowband filter of the tunable narrowband filters is configured to filter the respective wireless transmission signal; a power detector configured, for a given wireless signal of the wireless transmission signals, to detect a forward and reflected power of the given wireless signal at the transmission antenna; a phase detector configured to detect a phase of the given wireless signal at the transmission antenna, thereby enabling a determination of a phase change in a modulated digital RF signal associated with the given wireless signal; and a controller configured to determine the phase change, based on the detected phase, and further configured, based on the detected forward and reflected power and the phase change, to tune a given tunable narrowband filter, of the tunable narrowband filters, that filters the given wireless signal, thereby improving a suppression, by the given tunable narrowband filter, of undesired frequency components in the given wireless signal.

In some cases, each of the tunable narrowband filters includes a plurality of switches, wherein the controller is configured to tune the tunable narrowband filters by controlling the switches of the tunable narrowband filters.

In some cases, the switches are PIN diodes.

In some cases, by tuning the given tunable narrowband filter, a transmission power of the given wireless signal at the transmission antenna is increased.

In some cases, the wireless communications system further comprises one or more tunable delay lines coupled between the narrowband filters bank and the transmission antenna, and configured to control an electrical length of an electrical cable that is coupled between the narrowband filters bank and the transmission antenna; wherein the controller is further configured, based on the phase change, to tune at least one of the tunable delay lines to modify the electrical length of the electrical cable, thereby further suppressing the undesired frequency components in the given wireless signal.

In some cases, the wireless communications system further comprises one or more tunable capacitors, the tunable capacitors being coupled between the narrowband filters bank and the transmission antenna; wherein the controller is further configured, based on the detected forward and reflected power, to tune at least one of the tunable capacitors, thereby further suppressing the undesired frequency components in the given wireless signal.

In some cases, a receiver of the wireless communications system or of another wireless communications system is capable of receiving a sensitivity signal concurrently to a transmission of the given wireless signal, wherein a fundamental reception frequency over which the sensitivity signal is received is at an offset of two or more frequency channels from a fundamental transmission frequency over which the given wireless signal is transmitted.

In accordance with a second aspect of the presently disclosed subject matter, there is provided a wireless communications system, comprising: a transmitter configured to generate one or more wireless transmission signals; at least one filter, coupled between the transmitter and one or more tunable delay components, the filter being configured to filter the wireless transmission signals; the one or more tunable delay components, coupled between an output of the filter and a transmission antenna; a power detector configured, for a given wireless signal of the wireless transmission signals, to detect a forward and reflected power of the given wireless signal at the transmission antenna; a phase detector configured to detect a phase of the given wireless signal at the transmission antenna, thereby enabling a determination of a phase change in a modulated digital Radio Frequency (RF) signal associated with the given wireless signal; and a controller configured to determine the phase change, based on the detected phase, and further configured, based on the detected forward and reflected power and the phase change, to tune one or more given delay components of the tunable delay components, thereby increasing, at the transmission antenna, a transmission power of the given wireless signal.

In some cases, the given delay components include one or more tunable delay lines that are configured to control an electrical length of an electrical cable that is coupled between the filter and the transmission antenna; wherein at least one of the tunable delay lines is tuned to modify the electrical length of the electrical cable.

In some cases, the given delay components include one or more tunable capacitors.

In some cases, the at least one filter is a filters bank of filters.

In accordance with a third aspect of the presently disclosed subject matter, there is provided a method for suppressing undesired frequency components in a given wireless signal, the method comprising: generating, by a transmitter of a wireless communication system, the given wireless signal; filtering the given wireless signal, by a given tunable narrowband filter, the given tunable narrowband filter being one of a plurality of tunable narrowband filters in a narrowband filters bank, wherein the narrowband filters bank is coupled between the transmitter and a transmission antenna, and wherein the tunable narrowband filters are capable of operating at a Radio Frequency (RF) power of 50 Watts or more; detecting, by a power detector, a forward and reflected power of the given wireless signal at the transmission antenna; detecting, by a phase detector, a phase of the given wireless signal at the transmission antenna, thereby enabling a determination of a phase change in a modulated digital RF signal associated with the given wireless signal; determining, by a controller, the phase change; and tuning, by the controller, based on the detected forward and reflected power and the phase change, the given tunable narrowband filter, thereby improving a suppression, by the given tunable narrowband filter, of undesired frequency components in the given wireless signal.

In some cases, each of the tunable narrowband filters includes a plurality of switches, wherein the tuning of the given tunable narrowband filter is performed by controlling the switches of the given tunable narrowband filter.

In some cases, by tuning the given tunable narrowband filter, a transmission power of the given wireless signal at the transmission antenna is increased.

In some cases, one or more tunable delay lines are coupled between the narrowband filters bank and the transmission antenna, and configured to control an electrical length of an electrical cable that is coupled between the narrowband filters bank and the transmission antenna; wherein the method further comprises: tuning, by the controller, based on the phase change, at least one of the tunable delay lines, to modify the electrical length of the electrical cable, thereby further suppressing the undesired frequency components in the given wireless signal.

In some cases, one or more tunable capacitors are coupled between the narrowband filters bank and the transmission antenna; wherein the method further comprises: tuning, by the controller, based on the detected forward and reflected power, at least one of the tunable capacitors, thereby further suppressing the undesired frequency components in the given wireless signal.

In some cases, a receiver of the wireless communications system or of another wireless communications system is capable of receiving a sensitivity signal concurrently to a transmission of the given wireless signal, wherein a fundamental reception frequency channel over which the sensitivity signal is received is at an offset of two or more frequency channels from a fundamental transmission frequency over which the given wireless signal is transmitted.

In accordance with a fourth aspect of the presently disclosed subject matter, there is provided a method, comprising: generating, by a transmitter of a wireless communications system, a given wireless signal; filtering the given wireless signal, by at least one filter, the filter being coupled between the transmitter and one or more tunable delay components, and the one or more tunable delay components being coupled between an output of the filter and a transmission antenna; detecting, by a power detector, a forward and reflected power of the given wireless signal at the transmission antenna; detecting, by a phase detector, a phase of the given wireless signal at the transmission antenna, thereby enabling a determination of a phase change in a modulated digital Radio Frequency (RF) signal associated with the given wireless signal; determining, by a controller, the phase change; and tuning, by the controller, based on the detected forward and reflected power and the phase change, one or more given delay components of the tunable delay components, thereby increasing, at the transmission antenna, a transmission power of the given wireless signal.

In some cases, the given delay components include one or more tunable delay lines that are configured to control an electrical length of an electrical cable that is coupled between the filter and the transmission antenna; wherein at least one of the tunable delay lines is tuned to modify the electrical length of the electrical cable.

In some cases, the given delay components include one or more tunable capacitors.

### BRIEF DESCRIPTION OF THE DRAWINGS

In order to understand the presently disclosed subject matter and to see how it may be carried out in practice, the subject matter will now be described, by way of non-limiting examples only, with reference to the accompanying drawings. The dimensions of components and features shown in the drawings are chosen for convenience and clarity of presentation and are not necessarily to scale. In the drawings:

FIG. 1 is a block diagram schematically illustrating a first example of a wireless communications system, in accordance with the presently disclosed subject matter;

FIG. 2 is a block diagram schematically illustrating a second example of a wireless communications system, in accordance with the presently disclosed subject matter;

FIG. 3 is a graph that schematically illustrates one example of a signal strength of transmission signal components in a given wireless transmission signal that is output by the transmitter, in accordance with the presently disclosed subject matter;

FIG. 4 is a graph that schematically illustrates one example of an ideal frequency response for a tunable narrowband filter in the tunable narrowband filters bank, in accordance with the presently disclosed subject matter;

FIG. 5 is a graph that schematically illustrates one example of a distorted frequency response for a tunable narrowband filter in the tunable narrowband filters bank, in accordance with the presently disclosed subject matter;

FIG. 6 is a graph that schematically illustrates one example of a corrected frequency response for a tunable narrowband filter in the tunable narrowband filters bank, in accordance with the presently disclosed subject matter;

FIG. 7 is a block diagram schematically illustrating one example of a tunable narrowband filter in the tunable narrowband filters bank, in accordance with the presently disclosed subject matter;

FIG. 8 is a block diagram schematically illustrating one example of tunable delay components, in accordance with the presently disclosed subject matter; and

FIG. 9 is a flowchart illustrating one example of a sequence of operations for improved wireless communications, in accordance with the presently disclosed subject matter.

### DETAILED DESCRIPTION

In the following detailed description, numerous specific details are set forth in order to provide a thorough understanding of the presently disclosed subject matter. However, it will be understood by those skilled in the art that the presently disclosed subject matter may be practiced without these specific details. In other instances, well-known methods, procedures, and components have not been described in detail so as not to obscure the presently disclosed subject matter.

In the drawings and descriptions set forth, identical reference numerals indicate those components that are common to different embodiments or configurations.

Unless specifically stated otherwise, as apparent from the following discussions, it is appreciated that throughout the specification discussions utilizing terms such as “transmitting”, “filtering”, “detecting”, “tuning”, “controlling”, “delaying” or the like, include actions and/or processes, including, inter alia, actions and/or processes of a computer, that manipulate and/or transform data into other data, said data represented as physical quantities, e.g. such as electronic quantities, and/or said data representing the physical objects. The terms “computer”, “processor”, “processing circuitry” and “controller” should be expansively construed to cover any kind of electronic device with data processing capabilities, including, by way of non-limiting example, a personal desktop/laptop computer, a server, a computing system, a communication device, a smartphone, a tablet computer, a smart television, a processor (e.g. digital signal processor (DSP), a microcontroller, a field-programmable gate array (FPGA), an application specific integrated circuit (ASIC), etc.), a group of multiple physical machines sharing performance of various tasks, virtual servers co-residing on a single physical machine, any other electronic computing device, and/or any combination thereof.

As used herein, the phrase “for example,” “such as”, “for instance” and variants thereof describe non-limiting embodiments of the presently disclosed subject matter. Reference in the specification to “one case”, “some cases”, “other cases” or variants thereof means that a particular feature, structure or characteristic described in connection with the embodiment(s) is included in at least one embodiment of the presently disclosed subject matter. Thus the appearance of the phrase “one case”, “some cases”, “other cases” or variants thereof does not necessarily refer to the same embodiment(s).

It is appreciated that, unless specifically stated otherwise, certain features of the presently disclosed subject matter, which are, for clarity, described in the context of separate embodiments, may also be provided in combination in a single embodiment. Conversely, various features of the presently disclosed subject matter, which are, for brevity, described in the context of a single embodiment, may also be provided separately or in any suitable sub-combination.

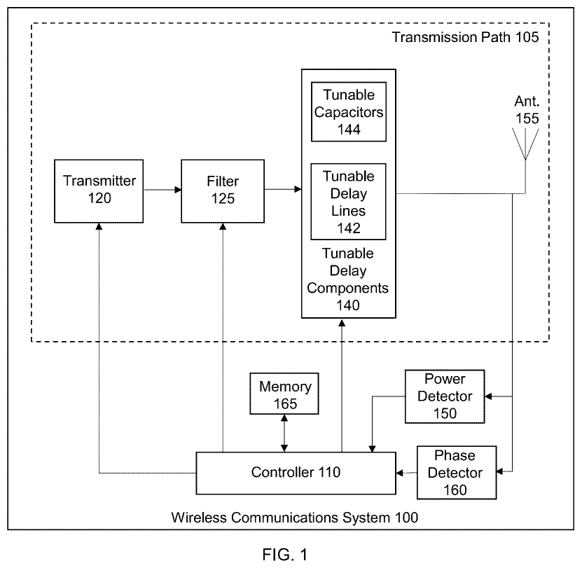

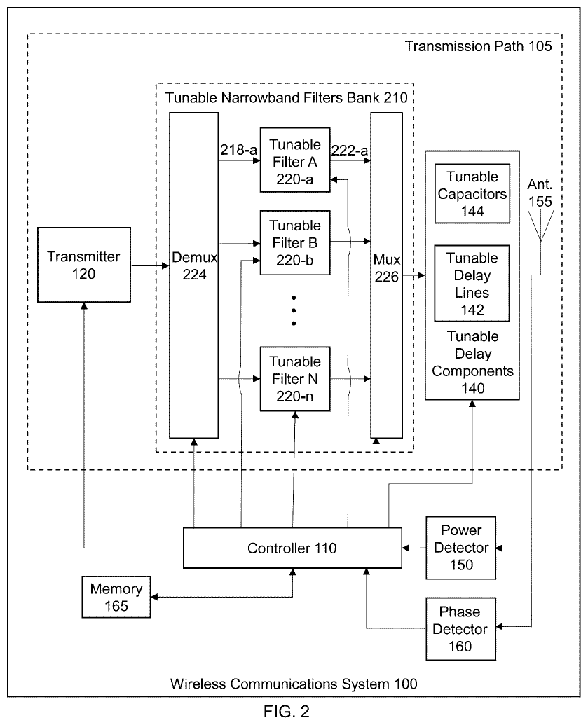

In embodiments of the presently disclosed subject matter, fewer, more and/or different stages than those shown in FIG. 9 may be executed. FIGS. 1 and 2 illustrate a general schematic of the architecture of a wireless communications system, in accordance with embodiments of the presently disclosed subject matter. Each module in FIGS. 1 and 2 can be made up of any combination of software, hardware and/or firmware that performs the functions as defined and explained herein. The modules in FIGS. 1 and 2 may be centralized in one location or dispersed over more than one location. In other embodiments of the presently disclosed subject matter, the system may comprise fewer, more, and/or different modules than those shown in FIGS. 1 and 2.

Any reference in the specification to a method should be applied mutatis mutandis to a system capable of executing the method and should be applied mutatis mutandis to a non-transitory computer readable medium that stores instructions that once executed by a computer result in the execution of the method.

Any reference in the specification to a system should be applied mutatis mutandis to a method that may be executed by the system and should be applied mutatis mutandis to a non-transitory computer readable medium that stores instructions that may be executed by the system.

Any reference in the specification to a non-transitory computer readable medium should be applied mutatis mutandis to a system capable of executing the instructions stored in the non-transitory computer readable medium and should be applied mutatis mutandis to method that may be executed by a computer that reads the instructions stored in the non-transitory computer readable medium.

Attention is now drawn to FIG. 1, a block diagram schematically illustrating a first example of a wireless communications system 100, in accordance with the presently disclosed subject matter.

In accordance with the presently disclosed subject matter, wireless communications system 100 is configured to include a transmission path 105 and a controller 110. Transmission path 105 is configured to include a transmitter 120 and at least one filter 125. In some cases, wireless communications system 100 is a radio system.

Controller 110 can include one or more processing units (e.g. central processing units), microprocessors, microcontrollers (e.g. microcontroller units (MCUs)) or any other computing devices or modules, including multiple and/or parallel and/or distributed processing units, which are adapted to independently or cooperatively process data for controlling relevant resources of the wireless communications system 100 and for enabling operations related to the resources of the wireless communications system 100.

Controller 110 is configured to provide the transmitter 120 with transmission data. Transmitter 120 is configured to generate one or more wireless transmission signals that include the transmission data, for transmission by a transmission antenna 155. In some cases, the transmitter 120 has a Radio Frequency (RF) power that is greater than 50 Watts (e.g., 55 Watts, 60 Watts, 70 Watts, 80 Watts, 90 Watts, 100 Watts, 125 Watts, 150 Watts, 175 Watts, 200 Watts, etc.). The one or more wireless transmission signals that are generated by the transmitter 120 include undesired frequency components, including, inter alia, transmitter noise and/or harmonics of the transmission carrier frequencies of the wireless transmission signals.

The at least one filter 125 is coupled between the transmitter 120 and the transmission antenna 155, and is configured to suppress undesired frequency components in the wireless transmission signals, including, inter alia, harmonics of the transmission carrier frequencies of the wireless transmission signals. In some cases, the at least one filter 125 (for example, a low pass filter) is a tunable filter. In some cases, the at least one filter 125 is a filters bank of a plurality of filters. In some cases, the filters in the filters bank are tunable. In some cases, the filters bank is a tunable narrowband filters bank 210 (not shown in FIG. 1), as detailed further herein, inter alia with reference to FIG. 2.

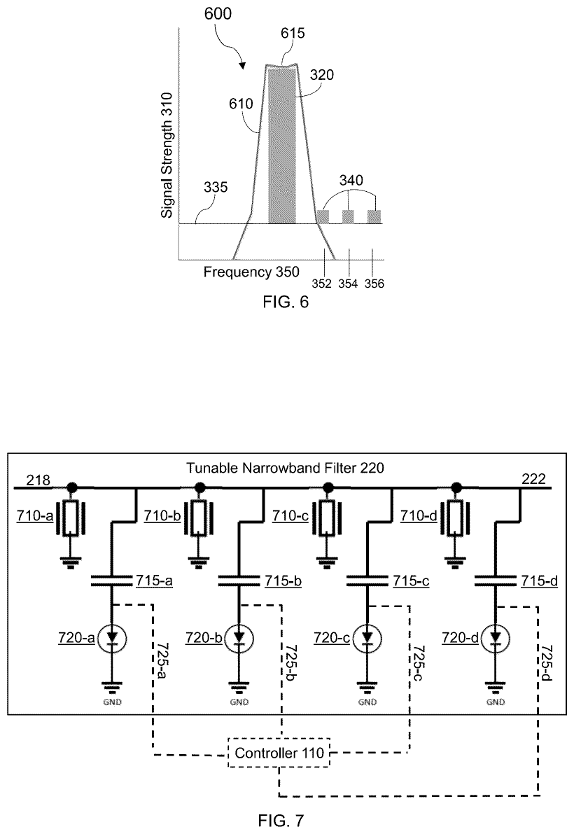

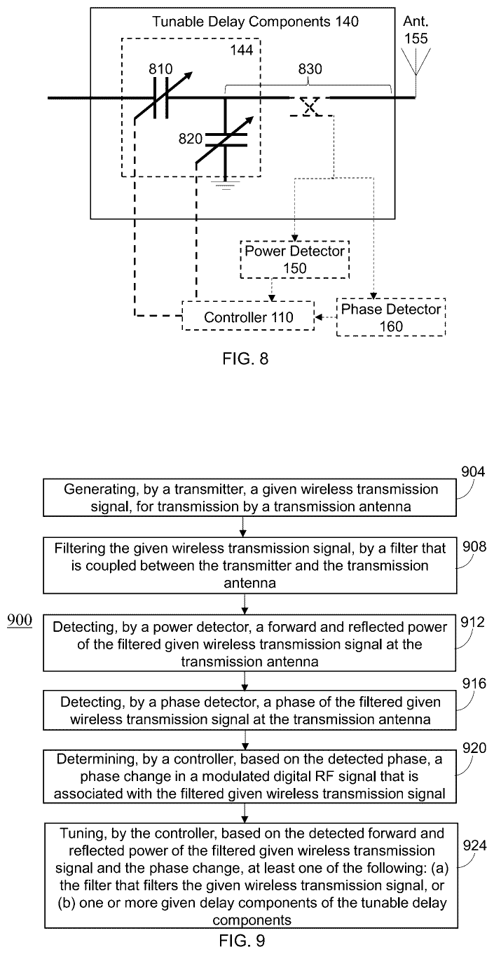

In some cases, transmission path 105 can be configured to include one or more tunable delay components 140 that are coupled between the filter 125 (or filters bank, e.g., tunable narrowband filters bank 210) and the transmission antenna 155. In some cases, by tuning one or more given delay components of the tunable delay components 140, the undesired frequency components in wireless transmission signals can be better suppressed, as detailed further herein, inter alia with reference to FIGS. 6 and 9. Moreover, and irrespective of the foregoing, by tuning one or more given delay components of the tunable delay components 140, a transmission power (i.e., a forward transmission power) of wireless transmission signals at the transmission antenna 155 can be increased. In some cases, the tunable delay components 140 include one or more tunable delay lines 142, as detailed further herein, inter alia with reference to FIG. 8. Additionally, or alternatively, in some cases, the tunable delay components 140 include one or more tunable capacitors 144, as detailed further herein, inter alia with reference to FIG. 8.

Wireless communications system 100 is further configured to include a coupler (not shown in FIG. 1), a power detector 150 and a phase detector 160. The coupler is configured to route part of each of the wireless transmission signals at the transmission antenna 155 to the power detector 150 and to the phase detector 160. Power detector 150 is configured, for each of the wireless transmission signals that it receives, to detect a forward power (i.e., a forward signal strength) and a reflected power (i.e., a reflected signal strength) of the respective wireless transmission signal. The reason that wireless transmission signals are reflected at the transmission antenna 155 is because the at least one filter 125 (or filters bank, e.g., tunable narrowband filters bank 210) is designed to operate with a transmission antenna having an ideal load, for example, 50 Ohms. Since an actual load of the transmission antenna 155 is different than the ideal load of the transmission antenna 155, reflected wireless transmission signals are reflected from the transmission antenna 155 towards the filter 125 (or filters bank, e.g., tunable narrowband filters bank 210). Phase detector 160 is configured, for each of the wireless transmission signals, to detect a phase of the respective wireless transmission signal.

Controller 110 is configured, based on the detected phases of each of the wireless transmission signals, to determine phase changes in modulated digital Radio Frequency (RF) signals that are associated with the wireless transmission signals. A respective phase change in a respective modulated digital RF signal of the modulated digital RF signals is a phase change between a known phase of the respective modulated digital RF signal that is provided by the transmitter 120 and a corresponding detected phase of the respective wireless transmission signal at the transmission antenna 155 that is associated with the respective modulated digital RF signal, wherein the phase change results from the passage of the RF signal through the transmission path 105 (including, inter alia, the filter 125, the tunable delay components 140, the electrical cable of the transmission antenna 155 and the transmission antenna 155).

Controller 110 is configured, based on the detected forward and reflected power of the wireless transmission signals at the transmission antenna 155 and the phase changes in the modulated digital Radio Frequency (RF) signals that are associated with the wireless transmission signals, to tune one or more tunable components in the wireless communications system 100. The tunable components that are tuned by the controller 110, responsive to the detected forward and reflected power of a respective wireless transmission signal and the phase change in the modulated digital RF signal associated with the respective wireless transmission signal, include at least one of the following: a given tunable filter (e.g., a given tunable narrowband filter 220 in a tunable narrowband filters bank 210), as detailed further herein, inter alia with reference to FIGS. 2, 7 and 9, or one or more given delay components of the tunable delay components 140, as detailed further herein, inter alia with reference to FIGS. 2, 8 and 9. By tuning tunable components in the wireless communications system 100, the reflected power of wireless transmission signals can be reduced, and accordingly the forward power of the wireless transmission signals can be increased.

In some cases, wireless communications system 100 can comprise or be otherwise associated with a memory 165 that is configured to store data. The stored data can include, for example, a look-up table (LUT), based on which the tuning of the tunable components in the transmission path 105 is performed, as detailed further herein, inter alia with reference to FIG. 9. In some cases, memory 165 can be further configured to enable retrieval and/or update and/or deletion of the stored data. It is to be noted that, in some cases, memory 165 can be distributed.

Attention is now drawn to FIG. 2, a block diagram schematically illustrating a second example of a wireless communications system 100, in accordance with the presently disclosed subject matter.

In accordance with the presently disclosed subject matter, wireless communications system 100 includes a transmission path 105 and a controller 110. Transmission path 105 is configured to include a transmitter 120 and at least one filter coupled between the transmitter 120 and a transmission antenna 155, as detailed earlier herein, inter alia with reference to FIG. 1. In some cases, wireless communications system 100 is a radio system.

Controller 110 can include one or more processing units (e.g. central processing units), microprocessors, microcontrollers (e.g. microcontroller units (MCUs)) or any other computing devices or modules, including multiple and/or parallel and/or distributed processing units, which are adapted to independently or cooperatively process data for controlling relevant resources of the wireless communications system 100 and for enabling operations related to the resources of the wireless communications system 100.

Controller 110 is configured to provide the transmitter 120 with transmission data. Transmitter 120 is configured to generate one or more wireless transmission signals that include the transmission data. In some cases, the transmitter 120 has a Radio Frequency (RF) power that is greater than 50 Watts, as detailed earlier herein, inter alia with reference to FIG. 1.

The one or more wireless transmission signals that are transmitted by the transmitter 120 include undesired frequency components, including, inter alia, transmitter noise and/or harmonics of the transmission carrier frequencies of the wireless transmission signals. The signal strength of undesired frequency components can be greater than at least one of: (a) a receiver sensitivity of a receiver (not shown in the figures) of the wireless communications system 100 or (b) a receiver sensitivity of another receiver (not shown) within the wireless communications network (not shown) over which the wireless communications system 100 communicates.

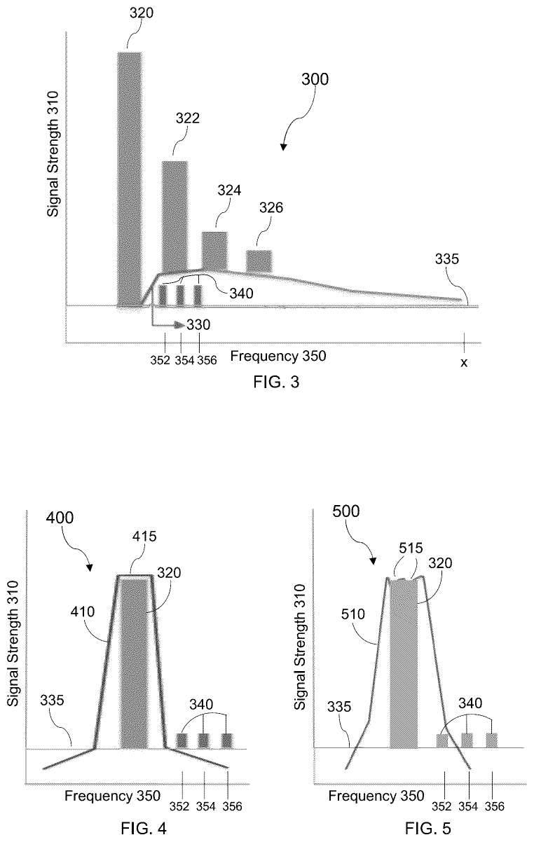

To illustrate this, attention is briefly drawn to FIG. 3, a graph 300 that schematically illustrates one example of a signal strength 310 of transmission signal components (320, 322, 324, 326, 330) in a given wireless transmission signal output by a transmitter 120, in accordance with the presently disclosed subject matter. The given wireless transmission signal includes transmission signal components (320, 322, 324, 326, 330) over a range of frequencies 350. The transmission signal components include a signal component at the fundamental (i.e., carrier) transmission frequency 320; signal components at the first, second and third harmonics (322, 324 and 326, respectively) of the fundamental transmission frequency 320; and transmitter noise 330 (i.e., noise generated by the transmitter 120). Ideally, the wireless transmission signals that are transmitted by the transmitter 120 only would include a signal component at the fundamental transmission frequency (e.g., 320). However, in practice, the wireless transmission signals include undesired frequency components (e.g., 322, 324, 326, 330), for example, due to the non-linearity of the power amplifier of the transmitter 120.

The undesired frequency components (e.g., 322, 324, 326, 330) in the wireless transmission signals can cause the receiver of the wireless communications system 100 or another receiver within the wireless communications network over which the wireless communications system 100 communicates to fail to detect received wireless signals (e.g., 340) that are received at the receiver, notwithstanding that the signal strength (e.g., 310) of the received wireless signals (e.g., 340) is greater than the receiver sensitivity (e.g., 335) of the receiver. Specifically, the receiver may fail to detect received wireless signals (e.g., 340) that would have been detectable by the receiver in the absence of the undesired frequency components (e.g., 322, 324, 326, 330) when the signal strength (e.g., 310) of the undesired frequency components (e.g., 322, 324, 326, 330) is greater than the signal strength (e.g., 310) of the received wireless signals (e.g., 340). For example, for a wireless communications system 100 that is a full-duplex wireless communications system (e.g., a full-duplex radio system) with a two channels offset, received wireless signals (e.g., 340) that are received by the wireless communications system 100 concurrently or substantially concurrently to the transmission of wireless transmission signals by the wireless communications system 100 may not be detectable, by the wireless communications system 100, due to the signal strength (e.g., 310) of the undesired frequency components (e.g., 322, 324, 326, 330) being greater than the receiver sensitivity (e.g., 335).

Turning specifically to FIG. 3, FIG. 3 illustrates a receiver sensitivity (335) of a receiver. The signal strength 310 of the second, third and fourth harmonics (322, 324, 326, respectively) and the transmitter noise 330 (at least up to the frequency ‘x’) is greater than the receiver sensitivity 335. In accordance with the graph 300 of FIG. 3, the receiver (e.g., of a full-duplex wireless communications system 100) is to receive three wireless signals 340 over fundamental (i.e., carrier) reception frequencies (352, 354, 356) that are offset from the fundamental transmission frequency 320 of a concurrently transmitted given wireless transmission signal (e.g., transmitted by the transmitter 120 of the full-duplex wireless communications system 100) by two or more frequency channels (e.g., two channels of 4 MHz). As shown in FIG. 3, undesired frequency components (322, 324, 326, 330) of a given wireless transmission signal interfere with the reception of the wireless signals 340, and accordingly significantly reduce the capability of the receiver to detect the wireless signals 340. Specifically, in FIG. 3, a first wireless signal of the wireless signals 340 is received over a first fundamental reception frequency 352. Both a second harmonic 322 of the given wireless transmission signal and transmitter noise 330 interfere with a reception of the first wireless signal, since the second harmonic 322 and the transmitter noise 330 are of a signal strength 310 at the first fundamental reception frequency 352 that is greater than the signal strength 310 of the first wireless signal (it is to be noted that, unlike in FIG. 3, the capability of the receiver to detect the wireless signals 340 may be significantly reduced only due to transmitter noise 330, and not due to harmonics, unless the harmonic is at the same frequency as the respective wireless signal—as is the case with the first wireless signal in FIG. 3). This results in a significant reduction of the capability of the receiver to detect the first wireless signal. Similarly, a second wireless signal of the wireless signals 340 is received over a second fundamental reception frequency 354. Both a second harmonic 322 of the given wireless transmission signal and transmitter noise 330 interfere with a reception of the second wireless signal, since the second harmonic 322 and the transmitter noise 330 are of a signal strength 310 at the second fundamental reception frequency 354 that is greater than the signal strength 310 of the second wireless signal. This results in a significant reduction of the capability of the receiver to detect the second wireless signal. In addition, a third wireless signal of the wireless signals 340 is received over a third fundamental reception frequency 356. Transmitter noise 330 interferes with a reception of the third wireless signal, since the transmitter noise 330 is of a signal strength 310 at the third fundamental reception frequency 356 that is greater than the signal strength 310 of the third wireless signal. This results in a significant reduction of the capability of the receiver to detect the third wireless signal.

In order to suppress undesired frequency components (e.g., 322, 324, 326, 330) in the wireless transmission signals that are generated by the transmitter 120, in some cases, the at least one filter in the transmission path 105 is a tunable narrowband filters bank 210, for example, as shown in FIG. 2. As shown in FIG. 2, the tunable narrowband filters bank 210 includes a plurality of tunable, highly-selective narrowband filters (e.g., 220-a, 220-b, . . . , 220-n). The narrowband filters (e.g., 220-a, 220-b, . . . , 220-n) are configured to suppress undesired frequency components (e.g., 322, 324, 326, 330) in the wireless transmission signals that are transmitted by the transmitter 120.

In some cases, transmission path 105 is configured to include one or more tunable delay components 140 that are coupled between the tunable narrowband filters bank 210 and the transmission antenna 155. The one or more tunable delay components 140 can include, for example, one or more tunable delay lines 142 and/or one or more tunable capacitors 144, as detailed further herein, inter alia with reference to FIG. 8.

Each of the tunable narrowband filters (e.g., 220-a, 220-b, . . . , 220-n) in the tunable narrowband filters bank 210 is configured to operate most effectively to suppress undesired frequency components (e.g., 322, 324, 326, 330) in wireless transmission signals (i.e., is configured to have an ideal frequency response) for an ideal load of the transmission antenna 155. A non-limiting example for the ideal load for the transmission antenna 155 is 50 Ohms. FIG. 4 is a graph 400 that schematically illustrates one example of an ideal frequency response 410 for a tunable narrowband filter (e.g., 220-a, 220-b, . . . , or 220-n) in the tunable narrowband filters bank 210, in accordance with the presently disclosed subject matter. As illustrated in FIG. 4, a tunable narrowband filter (e.g., 220-a, 220-b, . . . , or 220-n) having an ideal frequency response 410 passes the transmission signal component of a wireless transmission signal that is at the fundamental transmission frequency 320 while filtering out all of the transmission signal components of the wireless transmission signal that are at an offset of two or more frequency channels from the fundamental transmission frequency 320. The ideal tunable narrowband filter (e.g., 220-a, 220-b, . . . , or 220-n) has a flat frequency response 415 at its peak. FIG. 4 illustrates the signal strength 310 of three wireless signals 340 that are received by a receiver (e.g., of a full-duplex wireless communications system) over fundamental (i.e., carrier) reception frequencies (352, 354, 356) that are offset from the fundamental transmission frequency 320 by two or more frequency channels (e.g., each having a bandwidth of 4 MHz). In the absence of the tunable narrowband filter (e.g., 220-a, 220-b, . . . , or 220-n), undesired frequency components (e.g., 322, 324, 326, 330) of the wireless transmission signal would interfere with the reception of the wireless signals 340, as detailed earlier herein, inter alia with reference to FIG. 3. However, the tunable narrowband filter (e.g., 220-a, 220-b, . . . , or 220-n) (in FIG. 4, having an ideal frequency response 410) filters out undesired frequency components (e.g., 322, 324, 326, 330) of the wireless transmission signal, thereby reducing or eliminating an effect of the undesired frequency components (e.g., 322, 324, 326, 330) on the capability of the receiver to detect sensitivity signals (i.e., received signals having a signal strength 310 above the receiver sensitivity 335 of the receiver) that are offset from the fundamental transmission frequency 320 by two or more frequency channels, without raising the receiver sensitivity 335.

In operation, the actual load of the transmission antenna 155 is different than its ideal load, thereby degrading the highly-selective passband characteristics of the tunable narrowband filters (e.g., 220-a, 220-b, . . . , 220-n). Specifically, when the actual load of the transmission antenna 155 is different than its ideal load, reflected wireless transmission signals are reflected from the transmission antenna 155 towards the tunable narrowband filters bank 210. This results in one or more depressions being formed in the passbands of the tunable narrowband filters (220-a, 220-b, . . . , 220-n) (i.e., the tunable narrowband filters have a non-unity gain in their passbands), thereby reducing the effectiveness of the tunable narrowband filters (220-a, 220-b, . . . , 220-n) in suppressing undesired frequency components (e.g., 322, 324, 326, 330).

To illustrate this, attention is now drawn to FIG. 5, a graph 500 that schematically illustrates one example of a distorted frequency response 510 for a tunable narrowband filter (e.g., 220-a, 220-b, . . . , or 220-n) in the tunable narrowband filters bank 210, in accordance with the presently disclosed subject matter. The distorted frequency response 510 is due to the actual load of the transmission antenna 155 being different than its ideal load. As shown in FIG. 5, the distorted frequency response 510 includes one or more depressions 515 formed in the passband of the tunable narrowband filter (e.g., 220-a, 220-b, . . . , or 220-n). Due to the distorted frequency response 510, the effectiveness of the tunable narrowband filter (e.g., 220-a, 220-b, . . . , or 220-n) in suppressing undesired frequency components (e.g., 322, 324, 326, 330) is reduced.

Turning again to FIG. 2, in order to improve the passband characteristics of any one of the tunable narrowband filters (e.g., 220-a, 220-b, . . . , 220-n) that passes a wireless transmission signal, wireless communications system 100 can be configured to reduce a reflected power of the wireless transmission signal at the transmission antenna 155, notwithstanding the difference between the actual load of the transmission antenna 155 and its ideal load. To achieve this, wireless communications system 100 can be configured to tune at least one tunable component in the transmission path 105, being at least one of: (a) the respective tunable narrowband filter (e.g., 220-a, 220-b, . . . , or 220-n) that passes the wireless transmission signal or (b) one or more given delay components of the tunable delay components 140, as detailed further herein, inter alia with reference to FIGS. 7 to 9. By improving the passband characteristics of the respective tunable narrowband filter (e.g., 220-a, 220-b, . . . , or 220-n), the respective tunable narrowband filter can be configured to better filter out undesired frequency components (e.g., 322, 324, 326, 330) in the wireless transmission signal that are at an offset of two or more frequency channels from a fundamental transmission frequency 320 of the wireless transmission signal.

To illustrate the improved passband characteristics of a tunable narrowband filter (e.g., 220-a, 220-b, . . . , or 220-n) in the tunable narrowband filters bank 210 due to the tuning of the at least one tunable component in the transmission path 105, as defined above, attention is now drawn to FIG. 6. FIG. 6 is a graph 600 that schematically illustrates one example of a corrected frequency response 610 for a tunable narrowband filter (e.g., 220-a, 220-b, . . . , 220-n) in the tunable narrowband filters bank 210, in accordance with the presently disclosed subject matter. As illustrated in FIG. 6, the difference between the corrected frequency response 610 and the ideal response for the tunable narrowband filter (e.g., 220-a, 220-b, . . . , 220-n) is less than the difference between the distorted frequency response 510 and the ideal response for the tunable narrowband filter (i.e., there is less distortion 615 in the corrected frequency response 610 than in the distorted frequency response 510).

Returning to FIG. 2, controller 110 is configured to tune tunable components in order to reduce the reflected power of wireless transmission signals at the transmission antenna 155, and thereby improve the passband characteristics of the tunable narrowband filters (e.g., 220-a, 220-b, . . . , 220-n) (i.e., provide a corrected frequency response (e.g., 610) for the tunable narrowband filters). Specifically, at least one of the following can be tuned, by the controller 110, based on the forward and reflected power of any one of the wireless transmission signals and a phase change in a modulated digital Radio Frequency (RF) signal associated with the respective wireless transmission signal: (a) the respective tunable narrowband filter (e.g., 220-a, 220-b, . . . , or 220-n) that passes the respective wireless transmission signal or (b) one or more given delay components of the tunable delay components 140, as detailed further herein, inter alia with reference to FIGS. 7 to 9.

Controller 110 can also be configured to select the tunable narrowband filter (e.g., tunable filter A 220-a) in the tunable narrowband filters bank 210 that is to filter a respective wireless transmission signal that is transmitted by the transmitter 120. This can be achieved, for example, by controlling a demultiplexer 224 and a multiplexer 226 of the tunable narrowband filters bank 210, using the controller 110, to pass the respective wireless transmission signal via the selected tunable narrowband filter (e.g., tunable filter A 220-a).

Wireless communications system 100 is configured to include a coupler (not shown in FIG. 2), a power detector 150 and a phase detector 160. The coupler is configured to route parts of wireless transmission signals at the transmission antenna 155 to the power detector 150 and to the phase detector 160. Power detector 150 is configured, for each of the wireless transmission signals that it receives, to detect a forward power and a reflected power of the respective wireless transmission signal. Phase detector 160 is configured, for each of the wireless transmission signals, to detect a phase of the respective wireless transmission signal.

Controller 110 is configured, based on the detected phases of each of the wireless transmission signals, to determine phase changes in modulated digital Radio Frequency (RF) signals that are associated with the wireless transmission signals. A respective phase change in a respective modulated digital RF signal of the modulated digital RF signals is a phase change between a known phase of the respective modulated digital RF signal that is provided by the transmitter 120 and a corresponding detected phase of the respective wireless transmission signal at the transmission antenna 155 that is associated with the respective modulated digital RF signal, wherein the phase change results from the passage of the RF signal through the transmission path 105 (including, inter alia, the filter 125, the tunable delay components 140, the electrical cable of the transmission antenna 155 and the transmission antenna 155).

Controller 110 is configured, based on the detected forward and reflected power of a given wireless transmission signal at the transmission antenna 155, and further based on a phase change in a modulated digital RF signal that is associated with the given wireless transmission signal, to tune the given tunable narrowband filter (220-a, 220-b, . . . , or 220-n) that passes the given wireless transmission signal. This can result in the reflected power at the transmission antenna 155 being reduced, thereby improving the passband characteristics of the given tunable narrowband filter 220. The improved passband characteristics of the given tunable narrowband filter 220 yields an improved suppression of undesired frequency components (e.g., 322, 324, 326, 330) in the given wireless transmission signal. Moreover, since the reflected power that is reflected from the transmission antenna 155 to the given tunable narrowband filter 220 is reduced, a forward power of the given wireless transmission signal at the transmission antenna 155 is increased.

In some cases, in addition to or as an alternative to tuning the given tunable narrowband filter 220 that passes a given wireless transmission signal to reduce the reflected power that is reflected from the transmission antenna 155 to the given tunable narrowband filter 220, controller 110 can be configured to tune one or more given delay components of the tunable delay components 140 to reduce the reflected power, as detailed further herein, inter alia with reference to FIGS. 8 and 9. This can enable further improving the passband characteristics of the given tunable narrowband filter 220, and further increasing a forward power of the given wireless transmission signal.

In some cases, the wireless communications system 100 can comprise or be otherwise associated with a memory 165 that is configured to store data. The stored data can be, for example, a look-up table (LUT), based on which the tuning of tunable components (at least one of: a respective tunable narrowband filter 220, one or more given delay components of the tunable delay components 140, etc.) in the wireless communications system 100 can be performed, as detailed further herein, inter alia with reference to FIG. 9. In some cases, memory 165 can be further configured to enable retrieval and/or update and/or deletion of the stored data. It is to be noted that, in some cases, memory 165 can be distributed.

Attention is now drawn to FIG. 7, a block diagram schematically illustrating one example of a tunable narrowband filter 220 in the tunable narrowband filters bank 210, in accordance with the presently disclosed subject matter.

In accordance with the presently disclosed subject matter, in some cases, each of the tunable narrowband filters (e.g., 220-a, 220-b, . . . , 220-n) in the wireless communications system 100 includes: (a) a plurality of resonators (e.g., 710-a, 710-b, 710-c, 710-d) that are capable of operating at a RF power of 50 Watts or more (e.g., 55 Watts, 60 Watts, 70 Watts, 80 Watts, 90 Watts, 100 Watts, 125 Watts, 150 Watts, 175 Watts, 200 Watts, etc.); (b) switches, for example, PIN diodes (e.g., 720-a, 720-b, 720-c, 720-d); and (c) capacitors (e.g., 715-a, 715-b, 715-c, 715-d). It is to be noted that the number of resonators, switches and capacitors in FIG. 7 are provided for illustrative purposes only and are not intended to be limiting.

Controller 110 can be configured to tune any one of the tunable narrowband filters (e.g., 220-a, 220-b, . . . , 220-n) by switching on and off the switches (e.g., PIN diodes 720-a, 720-b, 720-c, 720-d, etc.) of the respective tunable narrowband filter 220. The control signals that are provided by the controller 110 for switching on and off the switches (e.g., 720-a, 720-b, 720-c, 720-d) are identified in FIG. 7 by reference numerals 725-a, 725-b, 725-c and 725-d. By switching on and off the switches (e.g., 720-a, 720-b, 720-c, 720-d), the capacitance across the capacitors (e.g., 715-a, 715-b, 715-c, 715-d) is adjusted, thereby modifying the passband of the respective tunable narrowband filter 220. In some cases, the central frequency of the respective tunable narrowband filter 220 is modified based on the switching of the switches (e.g., 720-a, 720-b, 720-c, 720-d), but the bandwidth of the respective tunable narrowband filter 220 is constant (for example, 3 MHz, 4 MHz, 5 MHz, 6 MHz, 7 MHz, 8 MHz, etc.) at all times.

It is advantageous for the switches in the tunable narrowband filters (e.g., 220-a, 220-b, . . . , 220-n) to be PIN diodes (e.g., 720-a, 720-b, 720-c, 720-d), since this enables quickly tuning any one of the tunable narrowband filters (220-a, 220-b, . . . , 220-n), and a quick transition (e.g., of no more than a few microseconds) between different tunable narrowband filters 220.

Attention is now drawn to FIG. 8, a block diagram schematically illustrating one example of tunable delay components 140, in accordance with the presently disclosed subject matter.

In accordance with the presently disclosed subject matter, in some cases, wireless communications system 100 can be configured to include one or more tunable delay components 140 between at least one filter 125 and the transmission antenna 155, the at least one filter 125 being coupled between the transmitter 120 and the transmission antenna 155. In some cases, the at least one filter 125 is a tunable narrowband filters bank 210, in which case the tunable delay components 140 are coupled between the tunable narrowband filters bank 210 and the transmission antenna 155, as illustrated in FIG. 2.

In some cases, the tunable delay components 140 include one or more tunable capacitors 144, for example, tunable capacitors 810 and 820. Additionally, or alternatively, in some cases, the tunable delay components 140 include one or more tunable delay lines 142 (not shown in FIG. 8). The tunable delay lines 142 are configured to control an electrical length of an electrical cable 830 that is coupled between the at least one filter 125 (e.g., narrowband filters bank 210) and the transmission antenna 155.

Controller 110 can be configured to tune one or more given delay components of the tunable delay components 140 to optimize a matching of transmission path 105 components (filter 125, tunable delay components 140, electrical cable 830, transmission antenna 155, etc.) thereby reducing a reflected power of the wireless transmission signals. Controller 110 can be configured to tune at least one of the tunable capacitors 144, based on a forward and reflected power of any one of the wireless transmission signals at the transmission antenna 155. The forward and reflected power of the wireless transmission signals is detected by a power detector 150. Controller 110 can be configured to tune at least one of the tunable delay lines 142 for controlling the electrical length of the electrical cable 830, based on a phase change in the modulated digital RF signal associated with the respective wireless transmission signal, as detailed earlier herein, inter alia with reference to FIGS. 1 and 2. In order to determine the phase change, the phase of the respective wireless transmission signal is detected by the phase detector 160, as detailed earlier herein, inter alia with reference to FIGS. 1 and 2. Moreover, if the filter 125 is a given tunable narrowband filter 220, the tuning of the given delay components can reduce distortions in the frequency response of the given tunable narrowband filter 220, as detailed earlier herein, inter alia with reference to FIG. 6. In view of all of the foregoing, the reflected power of the respective wireless transmission signal can be reduced, and consequently a transmission power of the respective wireless transmission signal can be increased.

Attention is now drawn to FIG. 9, a flowchart illustrating one example of a sequence of operations 900 for improved wireless communications, in accordance with the presently disclosed subject matter.

In accordance with the presently disclosed subject matter, a transmitter 120 of a wireless communications system 100 is configured to generate a given wireless transmission signal, for transmission by a transmission antenna 155 (block 904). In some cases, the wireless communications system 100 can be a radio system, and the given wireless transmission signal can be a given radio signal.

Wireless communications system 100 can be configured to include at least one filter 125 that is coupled between the transmitter 120 and the transmission antenna 155, as detailed earlier herein, inter alia with reference to FIG. 1. The at least one filter 125 is configured to suppress undesired frequency components (e.g., 322, 324, 326, 330) in the wireless transmission signals that are transmitted by the transmitter 120, the undesired frequency components (e.g., 322, 324, 326, 330) including, inter alia, noise and/or harmonics of the fundamental (i.e., carrier) transmission frequencies of the wireless transmission signals. For the given wireless transmission signal that is transmitted by the transmitter 120 (block 904), the filter 125 (e.g., one of the tunable narrowband filters 220) is configured to filter the given wireless transmission signal (block 908). In some cases, the at least one filter 125 can be a filters bank that: (i) is coupled between the transmitter 120 and the transmission antenna 155 and (ii) has a plurality of filters. The filters bank can be, for example, a tunable narrowband filters bank 210 having a plurality of tunable narrowband filters (e.g., 220-a, 220-b, . . . , 220-n), as detailed earlier herein, inter alia with reference to FIGS. 2 and 7. In cases in which the at least one filter 125 is a filters bank, one of the filters in the filters bank, for example, a given tunable narrowband filter (e.g., 220-a, 220-b, . . . , 220-n) in the tunable narrowband filters bank 210, filters the given wireless transmission signal.

In some cases, following the filtering of the given wireless transmission signal, the filtered given wireless transmission signal is provided to the transmission antenna 155 without being delayed by tunable delay components 140. Alternatively, in some cases, wireless communications system 100 can be configured to include one or more tunable delay components 140 between the at least one filter 125 (e.g., the tunable narrowband filters bank 210) and the transmission antenna 155, as detailed earlier herein, inter alia with reference to FIGS. 1, 2 and 8, and the filtered given wireless transmission signal is delayed by the tunable delay components 140. This affects a time of arrival of the filtered given wireless transmission signal at the transmission antenna 155. In some cases, the tunable delay components 140 include one or more tunable delay lines 142 that are configured to control an electrical length of an electrical cable 830 that is coupled between the filter 125 (e.g., the tunable narrowband filters bank 210) and the transmission antenna 155, as detailed earlier herein, inter alia with reference to FIG. 8. Additionally, or alternatively, in some cases, the tunable delay components 140 include one or more tunable capacitors 144 that are coupled between the at least one filter 125 (e.g., the tunable narrowband filters bank 210) and the transmission antenna 155, as detailed earlier herein, inter alia with reference to FIG. 8.

Wireless communications system 100 is configured to include a power detector 150. Power detector 150 is configured, following the filtering of a given wireless transmission signal, and, optionally, the passage of the filtered given wireless transmission signal through the tunable delay components 140, to detect a forward and reflected power of the filtered given wireless transmission signal at the transmission antenna 155 (block 912).

Wireless communications system 100 also is configured to include a phase detector 160. Phase detector 160 is configured to detect a phase of the filtered given wireless transmission signal at the transmission antenna 155 (block 916).

Wireless communications system 100 is configured, e.g., using controller 110, to determine, based on the detected phase, a phase change in a modulated digital RF signal that is associated with the filtered given wireless transmission signal (block 920). The phase change is a phase change between a known phase of the modulated digital RF signal that is generated by the transmitter 120 and the detected phase of the filtered given wireless transmission signal.

Wireless communications system 100 is configured, e.g., using controller 110, to tune, based on the detected forward and reflected power of the filtered given wireless transmission signal and the phase change in the modulated digital Radio Frequency (RF) signal, at least one of the following: (a) the given tunable narrowband filter, of the tunable narrowband filters (e.g., 220-a, 220-b, . . . , 220-n), that filters the given wireless transmission signal, or (b) one or more given delay components of the tunable delay components 140, as detailed earlier herein, inter alia with reference to FIG. 8 (block 924). By tuning the given tunable narrowband filter 220 and/or one or more of the tunable delay components 140, based on the detected forward and reflected power and the phase change in the modulated digital RF signal, a suppression of the undesired frequency components (e.g., 322, 324, 326, 330) in the given wireless transmission signal can be improved, as detailed earlier herein, inter alia with reference to FIGS. 2 and 8. This can enable the detection of sensitivity signals, by a receiver (not shown) (e.g., the receiver of the wireless communications system 100) that would be otherwise not be detectable, as detailed earlier herein, inter alia with reference to FIG. 2. Moreover, by tuning the given tunable narrowband filter 220 and/or one or more of the tunable delay components 140, based on the detected forward and reflected power and the phase change in the modulated digital RF signal, a transmission power of the given wireless signal at the transmission antenna 155 can be increased.

In some cases, the tuning of the tunable components (e.g., at least one of: a given tunable narrowband filter 220, given delay components, etc.) is performed based on a look-up table (LUT). For example, the tuning can be performed based on at least some (e.g., all) of the following criterion: (a) the forward and reflected power that is reflected from the transmission antenna 155 to the filter 125 (e.g., tunable narrowband filters bank 210); (b) the transmission frequency 320 of a given wireless transmission signal that passes through the filter 125 (e.g., a respective tunable narrowband filter 220); (c) if a tunable filter (e.g., a given tunable narrowband filter 220) passes the given wireless transmission signal, the tunable filter; or (d) a phase change in the modulated digital RF signal that is associated with the given wireless transmission signal.

It is to be noted that, with reference to FIG. 9, some of the blocks can be integrated into a consolidated block or can be broken down to a few blocks and/or other blocks may be added. It is to be further noted that some of the blocks are optional. It should be also noted that whilst the flow diagrams are described also with reference to the system elements that realizes them, this is by no means binding, and the blocks can be performed by elements other than those described herein.

It is to be understood that the presently disclosed subject matter is not limited in its application to the details set forth in the description contained herein or illustrated in the drawings. The presently disclosed subject matter is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the present presently disclosed subject matter.

It will also be understood that the system according to the presently disclosed subject matter can be implemented, at least partly, as a suitably programmed computer. Likewise, the presently disclosed subject matter contemplates a computer program being readable by a computer for executing the disclosed method. The presently disclosed subject matter further contemplates a machine-readable memory tangibly embodying a program of instructions executable by the machine for executing the disclosed method.

1. A wireless communications system, comprising:
a transmitter configured to generate one or more wireless transmission signals;
a narrowband filters bank including a plurality of tunable narrowband filters that are capable of operating at a Radio Frequency (RF) power of 50 Watts or more, the narrowband filters bank being coupled between the transmitter and a transmission antenna, wherein, for each of the wireless transmission signals, a respective tunable narrowband filter of the tunable narrowband filters is configured to filter the respective wireless transmission signal;
a power detector configured, for a given wireless signal of the wireless transmission signals, to detect a forward and reflected power of the given wireless signal at the transmission antenna;
a phase detector configured to detect a phase of the given wireless signal at the transmission antenna, thereby enabling a determination of a phase change in a modulated digital RF signal associated with the given wireless signal; and
a controller configured to determine the phase change, based on the detected phase, and further configured, based on the detected forward and reflected power and the phase change, to tune a given tunable narrowband filter, of the tunable narrowband filters, that filters the given wireless signal, thereby improving a suppression, by the given tunable narrowband filter, of undesired frequency components in the given wireless signal.

2. The wireless communications system of claim 1, wherein each of the tunable narrowband filters includes a plurality of switches, and wherein the controller is configured to tune the tunable narrowband filters by controlling the switches of the tunable narrowband filters.

3. The wireless communications system of claim 2, wherein the switches are PIN diodes.

4. The wireless communications system of claim 1, wherein, by tuning the given tunable narrowband filter, a transmission power of the given wireless signal at the transmission antenna is increased.

5. The wireless communications system of claim 1, further comprising:
one or more tunable delay lines coupled between the narrowband filters bank and the transmission antenna, and configured to control an electrical length of an electrical cable that is coupled between the narrowband filters bank and the transmission antenna;
wherein the controller is further configured, based on the phase change, to tune at least one of the tunable delay lines to modify the electrical length of the electrical cable, thereby further suppressing the undesired frequency components in the given wireless signal.

6. The wireless communications system of claim 1, further comprising:
one or more tunable capacitors, the tunable capacitors being coupled between the narrowband filters bank and the transmission antenna;
wherein the controller is further configured, based on the detected forward and reflected power, to tune at least one of the tunable capacitors, thereby further suppressing the undesired frequency components in the given wireless signal.

7. The wireless communications system of claim 1, wherein a receiver of the wireless communications system or of another wireless communications system is capable of receiving a sensitivity signal concurrently to a transmission of the given wireless signal, wherein a fundamental reception frequency over which the sensitivity signal is received is at an offset of two or more frequency channels from a fundamental transmission frequency over which the given wireless signal is transmitted.

8. A wireless communications system, comprising:
a transmitter configured to generate one or more wireless transmission signals;
at least one filter, coupled between the transmitter and one or more tunable delay components, the filter being configured to filter the wireless transmission signals;
the one or more tunable delay components, coupled between an output of the filter and a transmission antenna;
a power detector configured, for a given wireless signal of the wireless transmission signals, to detect a forward and reflected power of the given wireless signal at the transmission antenna;
a phase detector configured to detect a phase of the given wireless signal at the transmission antenna, thereby enabling a determination of a phase change in a modulated digital Radio Frequency (RF) signal associated with the given wireless signal; and
a controller configured to determine the phase change, based on the detected phase, and further configured, based on the detected forward and reflected power and the phase change, to tune one or more given delay components of the tunable delay components, thereby increasing, at the transmission antenna, a transmission power of the given wireless signal.

9. The wireless communications system of claim 8, wherein the given delay components include one or more tunable delay lines that are configured to control an electrical length of an electrical cable that is coupled between the filter and the transmission antenna; and
wherein at least one of the tunable delay lines is tuned to modify the electrical length of the electrical cable.

10. The wireless communications system of claim 8, wherein the given delay components include one or more tunable capacitors.

11. The wireless communications system of claim 8, wherein the at least one filter is a filters bank of filters.

12. A method for suppressing undesired frequency components in a given wireless signal, the method comprising:
generating, by a transmitter of a wireless communication system, the given wireless signal;
filtering the given wireless signal, by a given tunable narrowband filter, the given tunable narrowband filter being one of a plurality of tunable narrowband filters in a narrowband filters bank, wherein the narrowband filters bank is coupled between the transmitter and a transmission antenna, and wherein the tunable narrowband filters are capable of operating at a Radio Frequency (RF) power of 50 Watts or more;
detecting, by a power detector, a forward and reflected power of the given wireless signal at the transmission antenna;
detecting, by a phase detector, a phase of the given wireless signal at the transmission antenna, thereby enabling a determination of a phase change in a modulated digital RF signal associated with the given wireless signal;
determining, by a controller, the phase change; and
tuning, by the controller, based on the detected forward and reflected power and the phase change, the given tunable narrowband filter, thereby improving a suppression, by the given tunable narrowband filter, of undesired frequency components in the given wireless signal.

13. The method of claim 12, wherein each of the tunable narrowband filters includes a plurality of switches, and wherein the tuning of the given tunable narrowband filter is performed by controlling the switches of the given tunable narrowband filter.

14. The method of claim 12, wherein, by tuning the given tunable narrowband filter, a transmission power of the given wireless signal at the transmission antenna is increased.

15. The method of claim 12, wherein one or more tunable delay lines are coupled between the narrowband filters bank and the transmission antenna, and configured to control an electrical length of an electrical cable that is coupled between the narrowband filters bank and the transmission antenna; and
wherein the method further comprises:
tuning, by the controller, based on the phase change, at least one of the tunable delay lines, to modify the electrical length of the electrical cable, thereby further suppressing the undesired frequency components in the given wireless signal.

16. The method of claim 12, wherein one or more tunable capacitors are coupled between the narrowband filters bank and the transmission antenna; and
wherein the method further comprises:
tuning, by the controller, based on the detected forward and reflected power, at least one of the tunable capacitors, thereby further suppressing the undesired frequency components in the given wireless signal.

17. The method of claim 12, wherein a receiver of the wireless communications system or of another wireless communications system is capable of receiving a sensitivity signal concurrently to a transmission of the given wireless signal, wherein a fundamental reception frequency channel over which the sensitivity signal is received is at an offset of two or more frequency channels from a fundamental transmission frequency over which the given wireless signal is transmitted.
